(19) United States
(12) Patent Application Publication
(10) Pub. No.: US 2025/0006478 A1
(43) Pub. Date: Jan. 2, 2025

(54) Pulse-Shaping Using A Sub-Region Tuning Apparatus And Method

(71) Applicant: MKS Instruments, Inc., Andover, MA (US)

(72) Inventors: Aaron BURRY, Rochester, NY (US); Nicholas NELSON, Rochester, NY (US)

(21) Appl. No.: 18/731,703

(22) Filed: Jun. 3, 2024

Related U.S. Application Data
(60) Provisional application No. 63/523,783, filed on Jun. 28, 2023.

(51) Int. Cl. H01J 37/32; H02M 3/04

(52) U.S. Cl. CPC H01J 37/3299; H02M 3/04

(57) ABSTRACT

A controller for a generator includes a feedforward control module. The feedforward control module is configured to generate an adjustment profile to control a parameter of a generator in accordance with a desired output signal. The feedforward control module generates a plurality of adjustment values in accordance with sub-regions of the output signal. Each sub-region includes a portion of the desired output signal.

### CROSS-REFERENCE TO RELATED APPLICATIONS

This application claims the benefit of U.S. Provisional Application No. 63/523,783, filed on Jun. 28, 2023. The entire disclosure of the above application is incorporated herein by reference.

### FIELD

The present disclosure relates to RF generator systems and to control of RF generators.

### BACKGROUND

Plasma processing is frequently used in semiconductor fabrication. In plasma processing, ions are accelerated by an electric field to etch material from or deposit material onto a surface of a substrate. In one basic implementation, the electric field is generated based on Radio Frequency (RF) or Direct Current (DC) power signals generated by a respective RF or DC generator of a power delivery system. The power signals generated by the generator must be precisely controlled to effectively execute plasma etching.

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. One general aspect includes a controller for a generator. The controller also includes a feedforward control module, the feedforward control module configured to generate an adjustment profile to control a parameter of a generator in accordance with a desired output signal. The feedforward control module generates a plurality of adjustment values in accordance with subregions of the output signal, where each sub-region includes a portion of the desired output signal. Other embodiments of this aspect include corresponding computer systems, apparatus, and computer programs recorded on one or more computer storage devices, each configured to perform the actions of the methods.

Implementations may include one or more of the following features. The controller where the feedforward control module receives a synchronization signal and where the synchronization signal indicates a relative position of the desired output signal. The desired output signal is a multistate pulse signal having a period. A sub-region may be one of a state of a multistate pulse of the desired output signal, a transition of the desired output signal, or an area of interest of the desired output signal. The feedforward control module includes a plurality of tuners, where each tuner provides feedforward control for a respective subregion. The feedforward control module includes a single tuner, where the single tuner provides feedforward control over each subregion and does not provide feedforward control for other than each subregion. The feedforward control module further may include: first memory for storing at least one prior actuator profile, wherein the prior actuator profile varies in accordance with at least one prior actuator profile; second memory for storing at least one prior output profile, where the prior output profile varies in accordance with the output of the generator; a learning module configured to receive the prior actuator profile and the prior output profile and generating the adjustment profile in accordance with at least one of at least one prior adjustment profile, the at least one prior actuator profile, and the at least one prior output profile. The generator is one of a voltage, current, or power generator. The generator is a RF generator. The feedforward control module allocates samples to each subregion in accordance with at least one of a number of available samples or a number of subregions. An equal number of samples are allocated to each sub-region. A different number of samples are allocated to a pair of sub-regions. Samples are allocated dynamically in accordance with at least one of smooth feedforward actuator content or magnitude of error. If a pair of subregions are arranged so that the allocated samples of each subregion partially overlap, the feedforward control module combines the pair of subregions to define a combined subregion. If a pair of subregions are arranged at an end of the desired output signal and at a beginning of a next the desired output signal and the allocated samples of each subregion partially overlap, the feedforward control module combines the pair of subregions to define a combined subregion. In each subregion, both feedback and feedforward control are used to control a parameter of the generator, and where for other than the sub-regions, one of feedforward or open loop control adjusts the parameter of the generator. Implementations of the described techniques may include hardware, a method or process, or computer software on a computer-accessible medium.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings.

FIG. 1 is a schematic block diagram of a power delivery system having multiple power supplies arranged according to various configurations of the present disclosure;

FIG. 2 shows waveforms of a time-varying signal and a pulse modulating the time-varying signal to describe a pulse mode of operation;

FIG. 3 shows a functional block diagram of a control system for a generator using feedback control;

FIG. 4 shows a comparison of setpoint and actual waveforms in one example of a control system for a generator using feedback control;

FIG. 5 shows a functional block diagram of a control system for a generator using feedback and feedforward control;

FIGS. 6A and 6B show waveforms comparing controlling a generator using only feedback control and controlling a generator using feedback and feedforward control;

FIG. 7 shows a functional block diagram of a control system for a generator using feedforward control;

FIG. 8 shows a functional block diagram of a control system for a generator having a multiple tuner feedforward control system for providing feedforward control in sub-regions of an envelope or pulse;

FIG. 9 shows a waveform depicting an example envelope of a desired output of a RF generator;

FIG. 10 shows waveforms describing operation of a first tuner arranged in accordance with the principles of the present disclosure;

FIG. 11 shows waveforms describing operation of a second tuner arranged in accordance with the principles of the present disclosure;

FIG. 12 shows a functional block diagram of an example control module arranged in accordance with various configurations; and

FIG. 13 shows a flow chart of operation of a control system arranged in accordance with the principals of the present disclosure.

In the drawings, reference numbers may be reused to identify similar and/or identical elements.

### DETAILED DESCRIPTION

A power system may include a DC or RF power generator or DC or RF generator, a matching network, collectively referred to as generator or generators, and a load (such as a process chamber, a plasma chamber, or a reactor having a fixed or variable impedance). The generator generates a DC power signal or a sinusoidal, RF, or other time-varying signal, which is received by the matching network or impedance optimizing controller or circuit. The matching network or impedance optimizing controller or circuit transforms a load impedance to a characteristic impedance of a transmission line between the generator and the matching network. The impedance matching aids in maximizing an amount of power delivered to the load (“delivered power”) and minimizing an amount of power reflected back from the load to the generator (“reverse power” or “reflected power”). Delivered power to the load may be maximized by minimizing reflected power when the input impedance of the matching network matches the characteristic impedance of the transmission line and generator.

In the power source or power supply field, there are typically two approaches to applying a power signal to the load. A first, more traditional approach is to apply a continuous power signal to the load. In a continuous mode or continuous wave mode, a continuous power signal is typically a constant DC, sinusoidal, or time-varying signal, which may be a RF or other power signal, that is output continuously by the power source to the load. In the continuous mode approach, the power signal assumes a constant DC or sinusoidal output, and the amplitude of the power signal and/or frequency (of a RF power signal) can be varied in order to vary the output power applied to the load.

A second approach to applying the power signal to the load involves pulsing a voltage, current, or power signal, rather than applying a continuous voltage, current, or power signal to the load. In a pulse or pulsed mode of operation, a voltage, current, or power signal is modulated by a modulation signal in order to define an envelope for the modulated power signal. The voltage, current, or power signal may be, for example, a sinusoidal RF signal or other time-varying signal. Power delivered to the load is typically varied by varying the modulation signal.

In a typical power supply configuration, output power applied to the load is determined by using sensors that measure the forward and reflected voltage, current, or power signal. Either set of these signals is analyzed in a control loop. The analysis typically determines a voltage, current, or power value which is used to adjust the output of the power supply in order to vary the voltage, current, or power applied to the load. In a power delivery system where the load is a process chamber or other nonlinear or time-varying load, the varying impedance of the load causes a corresponding varying of voltage, current, or power applied to the load, as applied voltage, current, or power is in part a function of the impedance of the load.

In systems where fabrication of various devices relies upon introduction of voltage, current, or power to a load to control a fabrication process, voltage, current, or power is typically delivered in one of two configurations. In a first configuration, voltage, current, or power is capacitively coupled to the load. Such systems are referred to as capacitively coupled plasma (CCP) systems. In a second configuration, the voltage, current, or power is inductively coupled to the load. Such systems are typically referred to as inductively coupled plasma (ICP) systems. Coupling to the plasma can also be achieved via wave coupling at microwave frequencies. Such an approach typically uses Electron Cyclotron Resonance (ECR) or microwave sources. Helicon sources are another form of wave coupled sources and typically operate at frequencies similar to that of conventional ICP and CCP systems. In various configurations, the Helicon sources may operate at RF frequencies. Power delivery systems may include at least one bias power and/or a source power applied to one or a plurality of electrodes of the load. The source power typically generates a plasma and controls plasma density, and the bias power modulates ions in the formulation of the sheath. The bias and the source may share the same electrode or may use separate electrodes, in accordance with various design considerations.

When a power delivery system drives a time-varying or nonlinear load, such as a process chamber or plasma chamber, the power absorbed by the bulk plasma and plasma sheath results in a density of ions with a range of ion energy. One characteristic measure of ion energy is the ion energy distribution function (IEDF). The ion energy distribution function (IEDF) can be controlled with the bias power or voltage. One way of controlling the IEDF for a system in which multiple voltage, current, or power signals are applied to the load occurs by varying multiple voltage, current, or power signals that are related by at least one of amplitude, frequency, and phase. The related at least one of amplitude, frequency, and phase of multiple voltage, current, or power signals may also be related by a Fourier series and the associated coefficients. The frequencies between the multiple voltage, current, or power signals may be locked, and the relative phase between the multiple voltage, current, or signals may also be locked. Examples of such systems can be found with reference to U.S. Pat. Nos. 7,602,127; 8,110,991; and 8,395,322, all assigned to the assignee of the present application and incorporated by reference in this application.

Time varying or nonlinear loads may be present in various applications. In one application, plasma processing systems may also include components for plasma generation and control. One such component is a nonlinear load implemented as a process chamber, such as a plasma chamber or reactor. A typical plasma chamber or reactor utilized in plasma processing systems, such as by way of example, for thin-film manufacturing, can utilize a dual power system. One voltage, current, or power generator (the source) controls the generation of the plasma, and the other voltage, current, or power generator (the bias) controls ion energy. Examples of dual power systems include systems that are described in U.S. Pat. Nos. 7,602,127; 8,110,991; and 8,395,322, referenced above. The dual power system described in the above-referenced patents employs a closed-loop control system to adapt power supply operation for the purpose of controlling ion density and its corresponding ion energy distribution function (IEDF).

Multiple approaches exist for controlling a process chamber, such as may be used for generating plasmas. For example, in voltage, current, or power delivery systems, phase and frequency of multiple driving signals operating at the same or nearly the same frequency may be used to control plasma generation. For such driven plasma sources, the periodic waveform affecting plasma sheath dynamics and the corresponding ion energy are generally known and are controlled by the frequency of the periodic waveforms and the associated phase interaction. Another approach in voltage, current, or power delivery systems involves dual frequency control. That is, two frequency sources operating at different frequencies are used to power a plasma chamber to provide substantially independent control of ion and electron densities. In various configurations, the frequency may be a RF frequency.

Another approach utilizes wideband RF power sources to drive a plasma chamber. A wideband approach presents certain challenges. One challenge is coupling the power to the electrode. A second challenge is that the transfer function of the generated waveform to the actual sheath voltage for a desired IEDF must be formulated for a wide process space to support material surface interaction. In one responsive approach in an inductively coupled plasma system, controlling power applied to a source electrode controls the plasma density while controlling power applied to the bias electrode modulates ions to control the IEDF to provide etch rate and etch feature profile control. By using source electrode and bias electrode control, the etch rate and other various etch characteristics are controlled via the ion density and energy.

As integrated circuit and device fabrication continues to evolve, so do the power requirements for controlling the process for fabrication. For example, with memory device fabrication, the requirements for bias voltage, current, or power continue to increase. Increased voltage, current, or power generates higher and more energetic ions for increased directionality or anisotropic etch feature profiles and faster surface interaction, thereby increasing the etch rate and allowing higher aspect ratio features to be etched. In one nonlimiting example, in some voltage, current, or power delivery systems, increased ion energy is sometimes accompanied by a lower bias frequency requirement along with an increase in the power and number of bias power sources coupled to the plasma sheath created in the plasma chamber. The increased power at a lower bias frequency and the increased number of bias power sources results in intermodulation distortion (IMD) from a sheath modulation. The IMD emissions can significantly reduce power delivered by the source where plasma generation occurs. U.S. Pat. No. 10,821,542, issued Nov. 3, 2020, entitled Pulse Synchronization by Monitoring Power in Another Frequency Band, assigned to the assignee of the present application, and incorporated by reference herein, describes a method of pulse synchronization by monitoring power in another frequency band. In the referenced U.S. patent application, the pulsing of a second RF generator is controlled in accordance with detecting at the second RF generator the pulsing of a first RF generator, thereby synchronizing pulsing between the two RF generators.

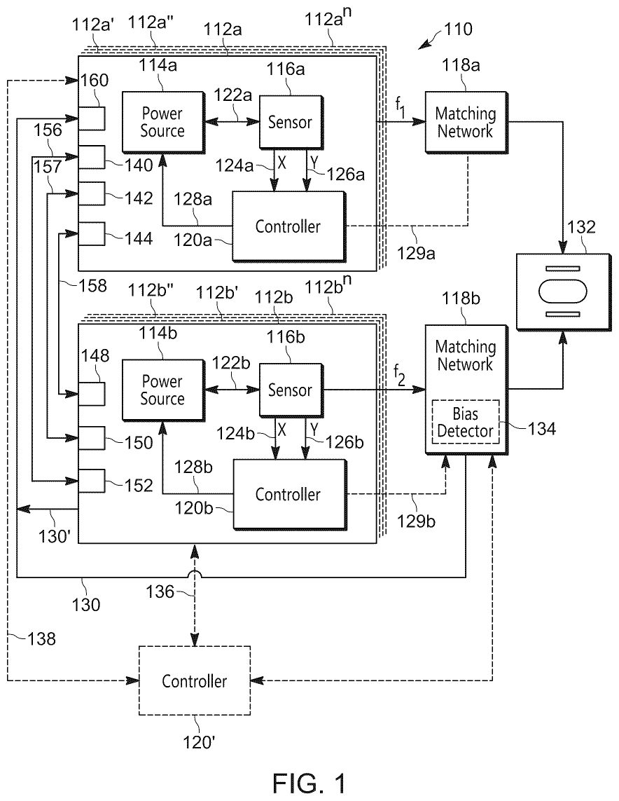

FIG. 1 depicts a RF generator or power supply system 110. Power supply system 110 includes a pair of radio frequency (RF) generators or power supplies 112a, 112b, matching networks 118a, 118b, and load 132, such as a nonlinear load, which may be a plasma chamber, plasma reactor, process chamber, and the like. In various configurations, generator 112a is referred to as a source generator or power supply, and matching network 118a is referred to as a source matching network. Further, in various configurations, one or both of voltage current, or power generators or power supplies 112a, 112b may output a continuous or pulsed time-varying voltage signal. Also in various configurations, generator 112b is referred to as a bias generator or power supply, and matching network 118b is referred to as a bias matching network. It will be understood that components can be referenced individually or collectively using the reference number with or without a letter subscript or a prime symbol. In various configurations, one or both of matching networks 118a, 118b may be implemented as a RF blocking filter, rather than an impedance match, such as may be the case for a matching network receiving a pulsed DC or nonsinusoidal signal. In various other configurations, one or both of matching networks 118a, 118b may be omitted.

In various configurations, source generator 112a receives a control signal 130 from matching network 118b, generator 112b, or a control signal 130′ from bias generator 112b. Control signals 130 or 130′ represent an input signal to source generator 112a that indicates one or more operating characteristics or parameters of bias generator 112b. In various configurations, a synchronization bias detector 134 senses the signal output from matching network 118b to load 132 and outputs synchronization or trigger signal 130 to source generator 112a. In various configurations, synchronization or trigger signal 130′ may be output from bias generator 112b to source RF generator 112a, rather than trigger signal 130. A difference between trigger or synchronization signals 130, 130′ may result from the effect of matching network 118b, which can adjust the phase between the input signal to and output signal from matching network. Signals 130, 130′ include information about the operation of bias RF generator 112b that in various configurations enables predictive responsiveness to address periodic fluctuations in the impedance of plasma chamber or load 132 caused by the bias generator 112b. When control signals 130 or 130′ are absent, generators 112a, 112b operate autonomously.

Generators 112a, 112b include respective power sources or amplifiers 114a, 114b, sensors 116a, 116b, and processors, controllers, or control modules 120a, 120b. Power sources 114a, 114b generate respective voltage, current, or power signals 122a, 122b, various configurations of which are described above, output to respective sensors 116a, 116b. RF power signals 122a, 122b. Signals 122a, 122b pass through sensors 116a, 116b and are provided to matching networks 118a, 118b as respective power signals f₁ and f₂. Sensors 116a, 116b output signals that vary in accordance with various parameters sensed from load 132. While sensors 116a, 116b, are shown within respective generators 112a, 112b, sensors 116a, 116b can be located externally to generators 112a, 112b. Such external sensing can occur at the output of the generator, at the input of an impedance matching device located between the generator and the load, or between the output of the impedance matching device (including within the impedance matching device) and the load.

Sensors 116a, 116b detect various operating parameters and output signals X and Y. Sensors 116a, 116b may include voltage, current, and/or directional coupler sensors. Sensors 116a, 116b may detect (i) voltage V and current I and/or (ii) forward power P_{FWD} output from respective power amplifiers 114a, 114b and/or RF generators 112a, 112b and reverse or reflected power P_{REV} received from respective matching networks 118a, 118b or load 132 connected to respective sensors 116a, 116b. The voltage V, current I, forward power P_{FWD}, and reverse power P_{REV} may be scaled, filtered, or scaled and filtered versions of the actual voltage, current, forward power, and reverse power associated with the respective power sources 114a, 114b. Sensors 116a, 116b may be analog or digital sensors or a combination thereof. In a digital implementation, the sensors 116a, 116b may include analog-to-digital (A/D) converters and signal sampling components with corresponding sampling rates. Signals X and Y can represent any of the voltage V and current I or forward (or source) power P_{FWD} reverse (or reflected) power P_{REV}.

Sensors 116a, 116b generate sensor signals X, Y, which are received by respective controllers or control modules 120a, 120b. Control modules 120a, 120b process the respective X, Y signals 124a, 126a and 124b, 126b and generate one or a plurality of feedforward or feedback control signals 128a, 128b to respective power sources 114a, 114b. Power sources 114a, 114b adjust voltage, current, or power signals 122a, 122b based on the received one or plurality feedback or feedforward control signal. In various configurations, control modules 120a, 120b may control matching networks 118a, 118b, respectively, via respective control signals 129a, 129b based on, for example, X, Y signals 124a, 126a and 124b, 126b. Control modules 120a, 120b may include one or more proportional-integral (PI), proportional-integral-derivative (PID), linear-quadratic-regulator (LQR) controllers or subsets thereof and/or direct digital synthesis (DDS) component(s) and/or any of the various components described below in connection with the modules.

In various configurations, control modules 120a, 120b may include functions, processes, processors, or submodules. Control signals 128a, 128b may be control or actuator drive signals and may communicate DC offset or rail voltage, voltage or current magnitude, frequency, and phase components, and the like. In various configurations, feedback control signals 128a, 128b can be used as inputs to one or multiple control loops. In various configurations, the multiple control loops can include a proportional-integral (PI), proportional-integral-derivative (PID) controllers, linear-quadratic-regulator (LQR) control loops, or subsets thereof, for RF drive, and for power supply rail voltage. In various configurations, control signals 128a, 128b can be used in one or both of a single-input-single-output (SISO) or multiple-input-multiple-output (MIMO) control scheme. An example of a MIMO control scheme can be found with reference to U.S. Pat. No. 10,546,724, issued on Jan. 28, 2020, entitled Pulsed Bidirectional Radio Frequency Source/Load, assigned to the assignee of the present application, and incorporated by reference herein. In other configurations, signals 128a, 128b can provide feedforward control as described in U.S. Pat. No. 10,049,857, issued Aug. 14, 2018, entitled Adaptive Periodic Waveform Controller, assigned to the assignee of the present application, and incorporated by reference herein.

In various configurations, power supply system 110 can include controller 120′. Controller 120′ may be disposed externally to either or both of generators 112a, 112b and may be referred to as external or common controller 120′. In various configurations, controller 120′ may implement one or a plurality of functions, processes, or algorithms described herein with respect to one or both of controllers 120a, 120b. Accordingly, controller 120′ communicates with respective generators 112a, 112b via a pair of respective links 136, 138 which enable exchange of data and control signals, as appropriate, between controller 120′ and generators 112a, 112b. For the various configurations, controllers 120a, 120b, 120′ can distributively and cooperatively provide analysis and control of generators 112a, 112b. In various other configurations, controller 120′ can provide control of generators 112a, 112b, eliminating the need for the respective local controllers 120a, 120b.

In various configurations, power source 114a, sensor 116a, controller 120a, and matching network 118a can be referred to as source RF power source 114a, source sensor 116a, source controller 120a, and source matching network 118a, respectively. Similarly in various configurations, RF power source 114b, sensor 116b, controller 120b, and matching network 118b can be referred to as bias power source 114b, bias sensor 116b, bias controller 120b, and bias matching network 118b, respectively. In various configurations and as described above, the source term refers to the generator or voltage, current, or power source that generates a plasma, and the bias term refers to the generator or voltage, current, or power source that tunes ion potential and the Ion Energy Distribution Function (IEDF) of the plasma. In various configurations, the source and bias power supplies operate at different frequencies or duty cycles. In various configurations, the source power supply operates at a higher frequency or duty cycle than the bias power supply. In various other configurations, the source and bias power supplies operate at the same frequencies or duty cycles or substantially the same frequencies or duty cycles.

According to various configurations, source generator 112a and bias generator 112b include multiple ports to communicate externally. Source generator 112a includes pulse envelope synchronization output port 140, digital communication port 142, RF output port 144, and control signal port 160. Bias generator 112b includes input port 148, digital communication port 150, and pulse synchronization input port 152. Pulse synchronization output port 140 outputs a pulse synchronization signal 156 to pulse synchronization input port 152 of bias generator 112b. Digital communication port 142 of source generator 112a and digital communication port 150 of bias generator 112b communicate via a digital communication link 157. Control signal port 160 of source generator 112a receives one or both of control signals 130, 130′. Output port 144 generates a control signal 158 input to input port 148. In various configurations, control signal 158 is substantially the same as the control signal controlling source generator 112a. In various other configurations, control signal 158 is the same as the control signal controlling source generator 112a, but is phase shifted within source generator 112a in accordance with a requested phase shift generated by bias generator 112b. Thus, in various configurations, source generator 112a and bias generator 112b are driven by substantially identical control signals or by substantially identical control signals phase shifted by a predetermined amount.

In various configurations, power supply system 110 may include multiple source generators 112a and multiple bias generators 112b. By way of nonlimiting example, a plurality of source generators 112a, 112a′, 112a″, . . . , 112a″ can be arranged to provide a plurality of output power signals to one or more source electrodes of load 132. Similarly, a plurality of bias generators 112b, 112b′, 112b″, . . . , 112b″ may provide a plurality of output power signals to a plurality of bias electrodes of load 132. When source generator 112a and bias generator 112b are configured to include a plurality of respective source generators or bias generators, each generator will output a separate signal to a corresponding plurality of matching networks 118a, 118b, configured to operate as described above, in a one-to-one correspondence. In various other configurations, there may not be a one-to-one correspondence between each generator and matching network. In various configurations, multiple source electrodes may refer to multiple electrodes that cooperate to define a composite source electrode. Similarly, multiple bias electrodes may refer to multiple connections to multiple electrodes that cooperate to define a composite bias electrode.

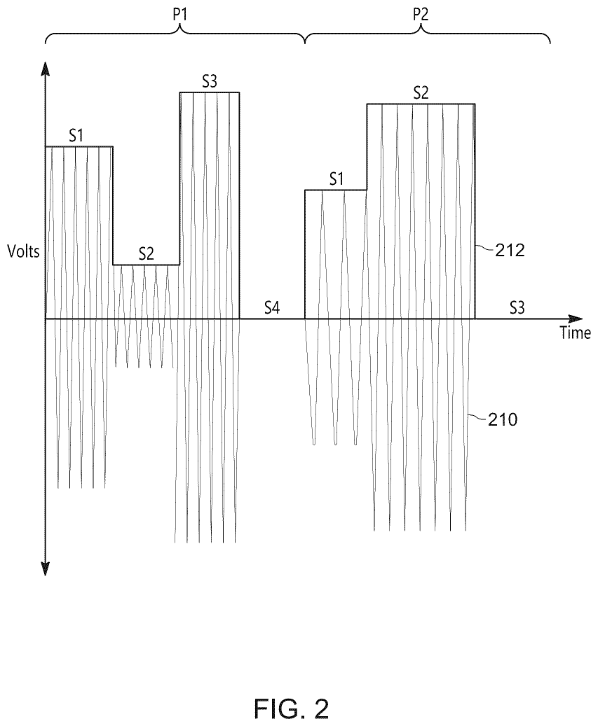

FIG. 2 depicts a plot of voltage versus time to describe a pulse or pulsed mode of operation for delivering voltage, current, or power to a load, such as load 132 of FIG. 1. More particularly, FIG. 2 depicts two multistate pulses P1, P2 of an envelope or pulse signal 212 having respective states S1-S4 and S1-S3. In FIG. 2, RF signal 210 is modulated by pulses P1 and P2, and, by way of nonlimiting example, is depicted as a RF sinusoidal signal or waveform. As shown at states S1-S3 of P1 and S1-S2 of P2, when the pulses are ON, RF generator 112 outputs RF signal 210 having an amplitude defined by the pulse magnitude of each state. Conversely, during states S4 of P1 and S3 of P2, the pulses are OFF, and generator 112 does not output signal 210. Pulses P1, P2 can repeat at a constant duty cycle or a variable duty cycle, and states S1-S4, S1-S3 of each respective pulse P1, P2 may have the same or varying amplitudes and widths.

In various configurations, signal 210 need not be implemented as a RF sinusoidal waveform as shown in FIG. 2. As referenced above with respect to FIG. 1, in addition to a sinusoidal waveform, in various configurations, signal 210 may be a nonsinusoidal waveform. By way of nonlimiting example, the RF signal 210 may be a rectangular waveform pulsed in a repeated or intermittent manner or a piecewise linear waveform as described in U.S. Pat. No. 10,396,601. In various configurations, pulse signal 212 may be other than a square wave as shown in FIG. 2. Further, by way of nonlimiting example, envelope or pulse signal 212 may be a single or multistate rectangular, trapezoidal, triangular, sawtooth, gaussian, or other shape that defines an envelope or modulating envelope of the underlying, modulated signal 210. In various configurations, pulse signal 210 may occur or reoccur within fixed or variable periods or time periods. In various other configurations, pulse signal 210 may vary in shape between each occurrence. In various other configurations, pulse signal 210 may occur or reoccur within fixed or variable time periods and vary in shape between each occurrence. Further yet, pulses P1, P2 can have multiple states S1, . . . , Sn of varying amplitude, duration, and shape. States S1, . . . , Sn may repeat within fixed or variable periods and may include all or a portion of the various shapes described above. Also shown in FIG. 2, signal 210 may operate at frequencies that vary between states or within a state.

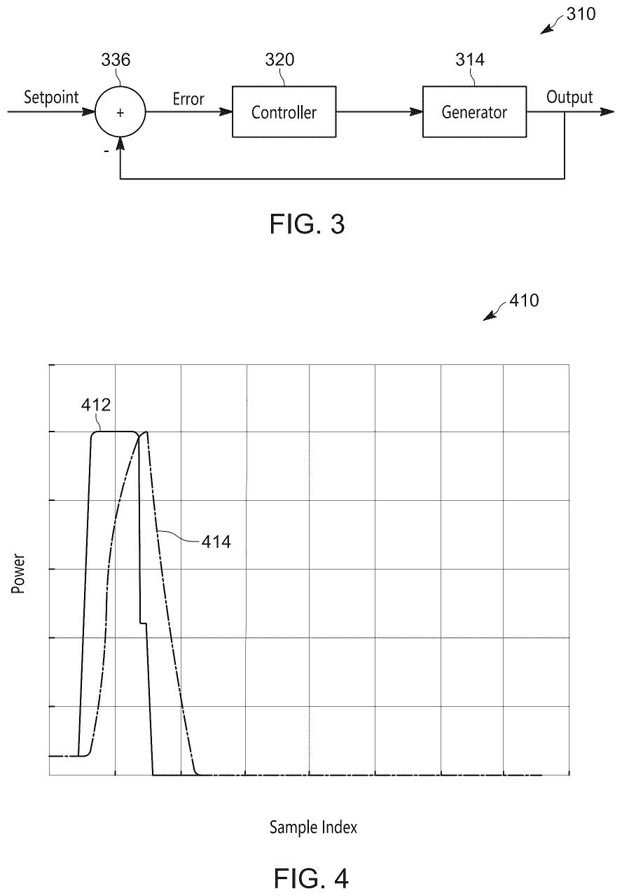

With reference to FIG. 3, FIG. 3 shows a functional block diagram of a portion of a power delivery system 310 for describing feedback control using a feedback control loop. In power delivery system 310, controller 320 outputs a control signal communicated to generator 314. Generator 314 operates as described above with respect to FIGS. 1 and 2 to output a voltage, current, or power signal to a load (not shown in FIG. 3), such as load 132 of FIG. 1. A parameter that varies in accordance with the voltage, current, or power signal output by generator 314 is sensed and communicated to summer 336. Summer 336 also receives a setpoint for the sensed parameter communicated to summer 336. Summer 336 determines a difference or error between the sensed parameter and the setpoint. The error indicates an amount of correction for controller 320 to apply in the next iteration of the feedback loop. In a typical feedback control system, controller 312 adjusts the control signal communicated to generator 314 to vary the output signal from generator 314 applied to the load in order to reduce or minimize the error.

FIG. 4 shows exemplary waveforms 410 further describing feedback control in one nonlimiting example of control or power delivery system 310. Waveforms 410 include desired or setpoint waveform 412 and actual waveform 414. In FIG. 4, the x-axis represents a sample index which indicates the indexes of the samples taken over time, and the y-axis represents power, but could represent parameters such as voltage or current. With reference to FIG. 3, desired or setpoint waveform 412 is communicated to summer 336, and actual waveform 414 is sensed at the output of generator 314 and communicated to the input of summer 336. As described above, summer 336 determines a difference between the waveforms to define an error signal input to controller 320.

In the feedback control system of FIG. 3, actual waveform 414 responds with a delay relative to desired or setpoint waveform 412. The delay in response of actual waveform 414 is a result of two components. A first component is the inherent delay in a feedback loop of a feedback control system, because the feedback controller responds to measured errors between setpoint and actual output. A second component is the delay or lag of the system being controlled, the generator and load in the nonlimiting example of FIGS. 3 and 4. A change in the input to generator 314 propagates to the output over time. Therefore, any feedback updates made by the controller will be delayed in reaching the output. While this delay can be addressed in part by increasing the gain of the feedback loop, the increased gain will reduce, but not eliminate, the delay. Increasing the gain, however, can result in an overshoot of actual waveform 414 relative to desired or setpoint waveform 412.

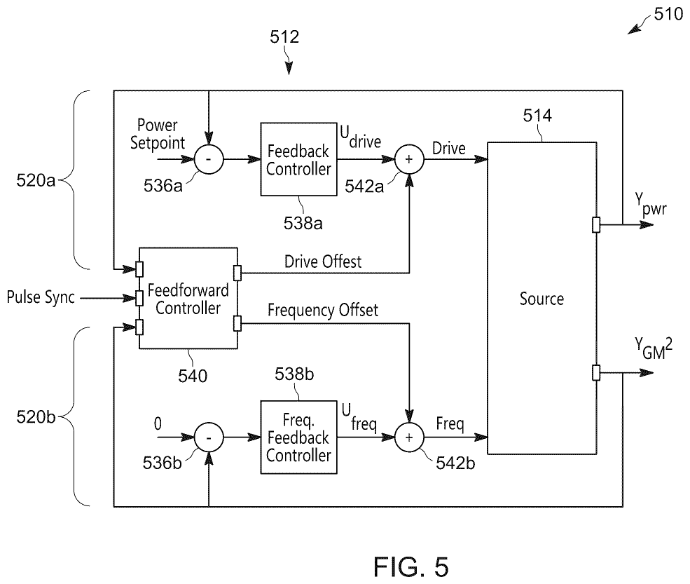

FIG. 5 shows a functional block diagram of control system 510 implementing both feedback control and feedforward control. Control system 510 includes a portion of a generator 512. Generator 512 includes first control section 520a and second control section 520b. Each control section 520a, 520b implements both feedback control and feedforward control. In one various configuration, first control section 520a provides voltage, current, or power control for an output source, and second control section 520b provides frequency control, such as for frequency tuning in order to improve impedance matching between the output source and a load (not shown).

First control section 520a includes feedback controller 538a which outputs drive control signal U_{drive} communicated to summer 542a. Output from summer 542a is a drive signal communicated to source 514. Source 514 operates as described above with respect to FIGS. 1-4, such as sources 114a, 114b. The drive signal output by summer 542a controls power output by source 514 in the configuration of FIG. 5, but may control one or more of frequency, voltage, current, or power. A parameter Y_{PWR} varies in accordance with the output of source 514 is sensed, such as via sensor 116 of FIG. 1, and communicated to summer 536a, similarly as described above with respect to FIG. 3. Summer 536a also receives a parameter setpoint value and determines a difference or error between the parameter setpoint value, which is power in the example of FIG. 5, and sensed parameter Y_{PWR} communicated to summer 536a. Thus, first control section 520a includes a feedback control loop for adjusting a drive signal to vary one or more of frequency, voltage, current, or power output from source 514.

Similarly, second control section 520b includes feedback controller 538b which outputs a drive control signal U_{freq} communicated to summer 542b. Output from summer 542b is a frequency signal communicated to source 514 to control the frequency of the signal output from source 514. Source 514 operates as described above with respect to FIGS. 1-4, such as sources 114a, 114b. A parameter Y_{gm}² that varies in accordance with the impedance match between source 514 and the load (not shown in FIG. 5) is determined and communicated to summer 536b, similarly as described above with respect to FIG. 3.

The frequency signal output by summer 542b determined in second control section 520b adjusts an operating frequency of source 514 in order to improve an impedance match between source 514 and the load. In various configurations, a parameter that varies in accordance with the impedance match is sensed or determined, such as via sensor 116 of FIG. 1, and communicated to summer 536a. In various configurations, summer 536b also receives a setpoint value for the parameter and determines a difference between the setpoint value and the sensed parameter. Thus, second control section 520b includes a feedback control loop for varying an impedance match between source 514 and the load. In various configurations, the impedance match varies in accordance with one or more of the reflected or reverse power (P_{REV}), the reflection coefficient (Γ), or the magnitude of the square of the reflection coefficient (|Γ²|). One or more of the parameters may be determined based on the output of source 514 and communicated to summer 536b. In one nonlimiting example, the magnitude squared of reflection coefficient, also referred to as the reflection ratio, Y_{gm}² is communicated to summer 536b. Because an impedance match is generally considered optimal when the reflection ratio (|Γ²|) is zero, the setpoint communicated to summer 536b is zero. It will be recognized that while the setpoint communicated to summer 536b is zero, the setpoint can be other than zero and vary in accordance the parameter used as a basis for feedback control.

The portions of first control section 520a and second control section 520b discussed above describe a feedback loop for controlling the respective parameters of interest. First control section 520a and second control section 520b each also include feedforward control loops. Control system 510 includes a feedforward controller 540. Feedforward controller 540 receives the respective envelope or pulse synchronization signal (PULSE SYNC) and generates respective drive adjustment or offset signal communicated to summer 542a and frequency adjustment or offset signal communicated to summer 542b. The adjustment or drive offset signal communicated to summer 542a is added to drive signal U_{DRIVE} communicated to summer 542a. Thus, summer 542a adds an adjustment or offset to drive signal U_{DRIVE} to provide feedforward control of the drive signal communicated to source 514. Similarly, a frequency adjustment or offset signal communicated to summer 542b is added to frequency signal U_{FREQ} communicated to summer 542b. Thus, summer 542b adds an adjustment or offset to drive signal U_{FREQ} to provide feedforward control of the frequency communicated to input to source 514. In various configurations, feedforward signals output by feedforward controller 540 may be added to the setpoints input to respective summers 536a, 536b, rather than to respective summers 542a, 542b. In such a configuration, summers 542a, 542b may be omitted.

In various configurations, the PULSE SYNC signal may be a timing signal to indicate a relative position of an envelope or pulse signal in order to synchronize the application of the respective drive adjustment or offset and frequency adjustment or offset. In various configurations, the PULSE SYNC signal may indicate a starting position of an envelope or pulse signal, such as envelope or pulse signal 212 of FIG. 2. In various configurations, the starting position may be a leading edge of the envelope or pulse. Based on a known pulse shape, stored feedforward control adjustments can be played back and applied relative to the PULSE SYNC signal. In various configurations, the pulse shape may be stored in memory, and the feedforward controller initiates playback based on the PULSE SYNC signal and the predetermined pulse shape stored in memory. In various other configurations, the PULSE SYNC signal may be a composite signal including both synchronization information and pulse shape information and playback of stored feedforward control adjustments occurs in a similar fashion. The composite signal may be communicated via one or both of serial communication or parallel communication protocols. In various configurations, the envelope or pulse shape may be a multistate pulse shape, such as envelope or pulse signal 212 of FIG. 2, and may modulate a carrier signal, such as a sinusoidal or other time-varying signal. One example of such a time-varying signal can be seen with respect to sinusoidal signal 216 of FIG. 2.

In various configurations, signals such as power Y_{PWR} or reflection ratio Y_{gm}² may be communicated to feedforward controller 540 so that feedforward controller 540 can determine how the output of source 514 varies in accordance with the correction, adjustment, or offset values communicated to respective summers 542a, 542b. Feedforward controller 540 may then adjust the output profiles to improve feedforward control. Examples of feedforward control can be found with respect to U.S. Pat. No. 10,049,857, referenced above; U.S. Pat. No. 11,715,624, issued on Aug. 1, 2023, entitled Adaptive Pulse Shaping With Post Match Sensor, assigned to the assignee of the present application; and U.S. patent application Ser. No. 18/302,141, entitled Enhanced Tuning Methods for Mitigating RF Load Impedance Variations Due to Periodic Disturbances; and all of which are incorporated by reference herein.

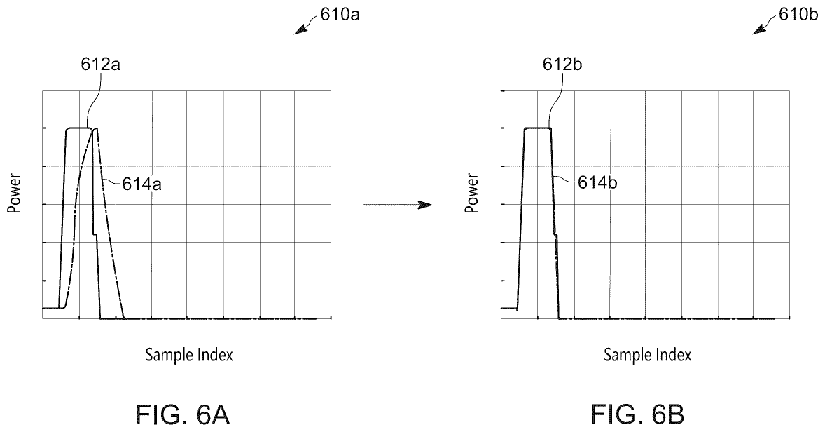

FIGS. 6A, 6B show a comparison between a feedback control only approach, as shown in FIG. 6A, and a combined feedback and feedforward control approach, as shown in FIG. 6B. In FIG. 6A, waveform 612a indicates the desired or setpoint of the parameter to be controlled, and waveform 614a shows the actual waveform of the parameter resulting using only feedback control. In FIG. 6B, waveform 612b indicates the desired or setpoint waveform of the parameter to be controlled, which is the same as waveform 612a, and waveform 614b shows the actual waveform of the parameter resulting using combined feedback and feedforward control. As can be seen in FIGS. 6A, 6B, waveform 614b represents an output waveform that is substantially similar to desired or setpoint waveforms 612a, 612b. Thus, combining feedforward control with feedback control provides a control approach that more accurately reproduces the desired or setpoint waveform 612a, 612b.

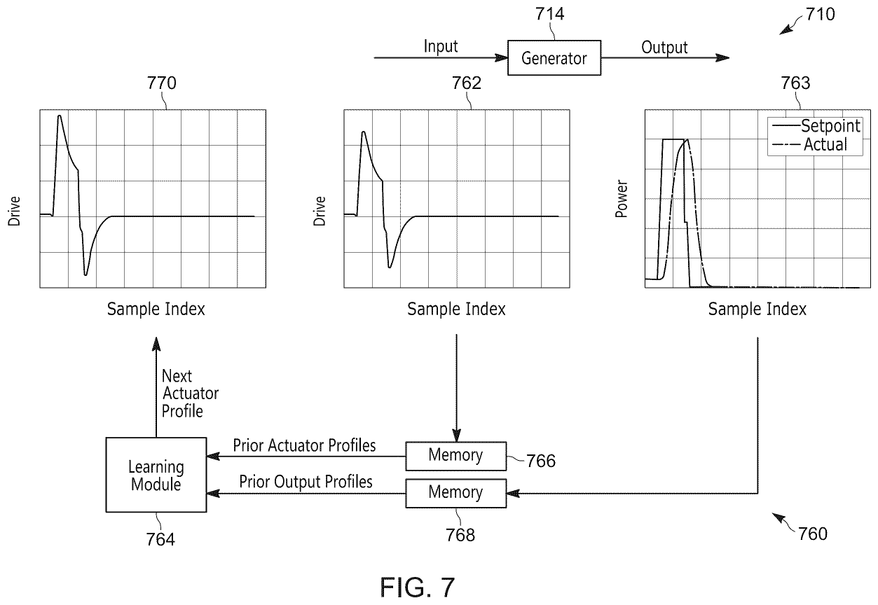

FIG. 7 shows a functional block diagram of a control system 710 for a generator using feedforward control, such as may be implemented in the feedforward control portion of first control section 520a or second control section 520b of FIG. 5, arranged in accordance with the principles of the present disclosure. Control system 710 includes generator 714 and feedforward control section 760, including at least one processor, module, or controller.

Feedforward control section 760 includes learning module 764, memory 766, and memory 768. It should be noted that while memory 766 and memory 768 are shown separately, memory 766 and memory 768 may reside in a common memory bank or reside in separate memory banks. Memory 766 and memory 768 are described individually with respect to FIG. 7 to indicate the different data that each memory stores.

Generator 714 receives feedforward control inputs in accordance with input actuator profile 762 and generates an output. The output from generator 714 determines an output profile 763. Output profile 763 may vary in accordance with one or more parameters sensed at the output of generator 714. Input actuator profile 762 is communicated to and stored in memory 766, and output profile 763 is communicated to and stored in memory 768. The profiles stored in respective memory 766 and memory 768 are input to learning module 764 as respective prior actuator profiles and prior output profiles. Learning module 764 compares respective prior actuator profiles and the prior output profiles and generates next actuator profile 770. Next actuator profile 770 represents a feedforward control input or control inputs communicated to generator 714 during the next control loop iteration of the feedforward controller.

In various configurations, next actuator profile 770 is the input profile applied to generator 714 one learning cycle later. By way of nonlimiting example, at time step k, input actuator profile u (k) and output profile y (k) are determined. Learning module 764 receives input actuator profile u (k) and output profile y (k) and determines the next actuator profile u (k+1), which corresponds to next actuator profile 770. Next actuator profile 770 is input to generator 714 at time step (k+1). As shown in FIG. 7, next actuator profile 770 has an amplitude greater than input actuator profile 762, though any number of characteristics of next actuator profile 770 may vary from step to step.

Precise control of output pulse shapes is a critical requirement for highly accurate generator control, such as RF generators, for applying voltage, current, or power to a load. As described above, to enable accurate pulse shape tracking performance, feedforward control is often used in conjunction with traditional feedback controllers. Feedforward control provides significantly higher control bandwidth and is less susceptible to delays experienced with feedback control. Thus, feedforward systems provide significant improvements in tracking desired pulse shape trajectories.

As described above with respect to FIG. 7, feedforward controllers typically use stored profiles of the actuator inputs and resulting outputs from one or more prior envelope or pulse periods to provide actuator updates. To achieve high fidelity pulse shapes commonly required in practice, high sampling rates are needed to generate envelope or pulse profiles to yield the desired high fidelity pulse shapes. In one nonlimiting example, a sampling period of 600 ns sampling is used to achieve accurate envelope or pulse shapes utilizing feedforward control.

In various plasma etching applications, integrated circuit fabrication recipes call for a range of pulse periods. In one nonlimiting example, integrated circuit fabrication recipes call for RF generators to operate across pulse periods from 100 Hz (10 millisecond pulse period) to 10 kHz (100 microsecond pulse period). For low repetition rate (i.e., long pulse period) applications, at sampling periods of 600 ns, large amounts of data are stored and processed for each iteration of the feedforward controller. In one nonlimiting example, using a 600 ns control sampling period, a 100 Hz pulse requires over 16,000 samples of data for each actuator and output in the system for one iteration of feedforward control. For approaches that leverage additional internal state information, such as estimating system slopes or gains at each sample location within the pulse period, the amount of memory and computational resources further increases. These resource requirements can limit the use of feedforward control approaches.

In order to mitigate the intensive resource requirements of feedforward control for low repetition rate pulsing, multiple feedforward tuners target sub-regions of the overall pulse period. Alternatively, operation of a feedforward single tuner is segmented to provide feedforward control only over selected regions of the pulse. These approaches reduce computational and memory requirements, since feedforward control applies over less than the entire pulse width. The remainder of the pulse will be controlled using one or both of feedback control or open loop control.

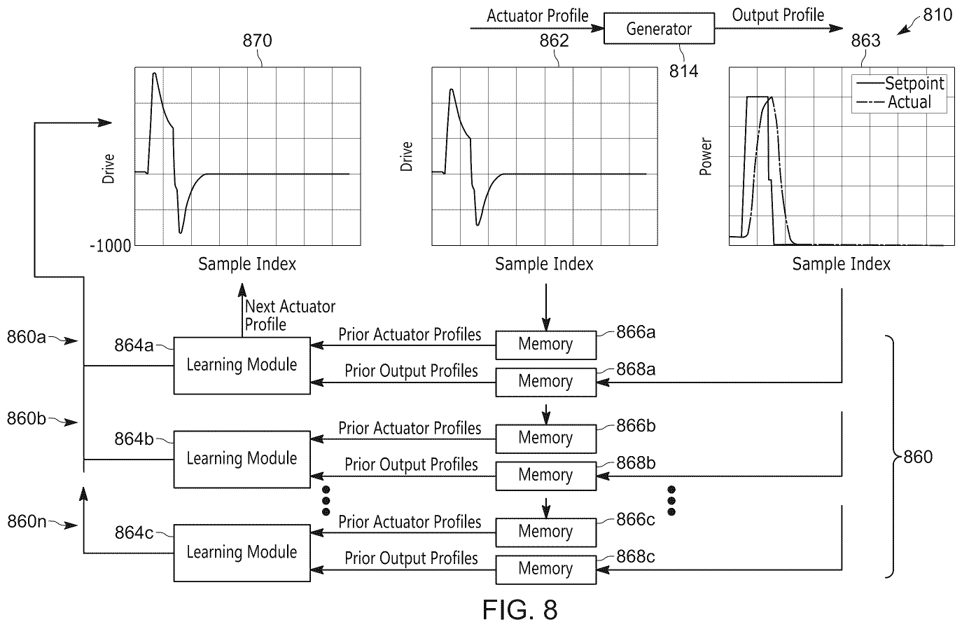

FIG. 8 shows a functional block diagram of a control system 810 for a generator using feedforward control, such as may be implemented in the feedforward control portion of first control section 520a or second control section 520b of FIG. 5, arranged in accordance with the principles of the present disclosure. The feedforward control system of FIG. 8 includes a plurality of tuners. As will be described in greater detail herein, each tuner provides feedforward control of selected portions of the envelope or pulse output by the generator. Control system 810 of FIG. 8 is configured similarly to the control system of FIG. 7. Control system 810 is further configured to include a feedforward tuner 860 having one or a plurality of feedforward tuners. The one or a plurality of feedforward tuners segment the envelope or pulse into sub-regions so that feedforward tuning occurs in predetermined sub-regions of the envelope or pulse to be controlled.

In various configurations, feedforward tuner 860 includes one or a plurality of feedforward tuners 860a, 860b, . . . , 860n. Each feedforward tuner 860a, 860b, . . . , 860n operates similarly to corresponding components described in FIG. 7. The individual components of each feedforward tuner 860a, 860b, . . . , 860n store and control based on samples taken over a predetermined portion, section, subsection, region, or sub-region, collectively referred to as a sub-region, of the envelope or pulse to be controlled. Since each feedforward tuner 860a, 860b, . . . , 860n is configured to operate on a sub-region of an envelope or pulse, only samples taken over the respective section of the envelope or pulse for which a particular feedforward tuner applies feedforward control are stored in corresponding memory and processed in the corresponding learning module. In various configurations, feedforward tuner 860 may include multiple feedforward tuners 860a, 860b, . . . , 860n. Multiple feedforward tuners 860a, 860b, . . . , 860n may apply the same or different algorithms to tune over the predetermined sub-region of the envelope or pulse. In various other configurations, feedforward tuner 860 may include a single feedforward tuner that is actuated over predetermined sub-regions of the envelope or pulse to enable feedforward control and deactuated over other predetermine sections of the envelope or pulse to disable feedforward control.

In various configurations, and as also described above, various combinations of feedback control, feedforward control, and open-loop control may be applied over the envelope or pulse. In various configurations, feedback control and feedforward control may be applied over selected sub-regions of the envelope or pulse. In various other configurations, only feedback control may be applied over selected sub-regions of the envelope or pulse. In various other configurations, only feedforward control may be applied over selected sub-regions of the envelope or pulse. In various other configurations, open-loop control may be applied over selected sub-regions of the envelope or pulse.

In various configurations, the envelope or pulse, such as envelope or pulse signal 212 of FIG. 2 may include multiple states S1, S2, . . . , Sn. The sub-regions of the envelope or pulse over which various feedback control, feedforward control, and open-loop control may be determined with reference to or independent of a particular state. Further yet, in various configurations, various feedforward control, feedback control, and open-loop control approaches may be determined in accordance with transitions of the envelope or pulse between selected states. In various further configurations, regions preceding a state transition may be included in the regions associated with the transitions. In this way, the region encompasses a set of samples that starts prior to the state transition and ends after the state transition. In various other configurations, various aspects of feedforward control, feedback control, and open-loop control approaches may be determined in accordance with the proximity of adjacent state transitions so that when transitions occur within a predetermined sampling width, feedforward control may be applied over the entire state, including the state transitions. In various other configurations, various aspects of feedforward control, feedback control, and open-loop control approaches may be determined in accordance with areas of interest in the output profile of the generator, independent of whether the areas of interest include state transitions.

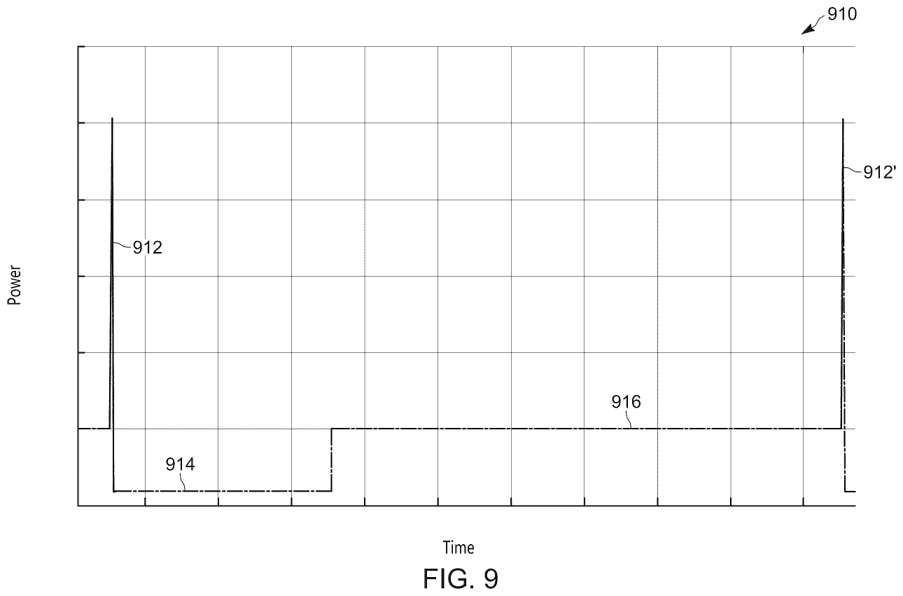

FIG. 9 shows envelope or pulse 910 having three states S1, S2, S3, referenced as 912, 914, 916, respectively. An additional state 912′ corresponds to state S1′ of the next envelope or pulse. State S1 has a width of approximately 25 μs, state S2 has a width of approximately 3 ms, and state S3 has a width of approximately 6.975 ms. Because the widths of states S2 and S3 are substantially longer than the width of state S1, applying only feedback control over states S2 and S3 typically provides sufficient accuracy so that the actual output or output profile satisfactorily approaches the desired output or output profile. In various other configurations, open-loop control could be applied over states S2 and S3.

State S1 is sufficiently narrow that applying open-loop or feedback control does not typically result in the actual output or output profile satisfactorily approaching the desired output or output profile. Applying feedforward control over state S1, either in combination with or independently from feedback control, provides improved fidelity between the actual output and the desired output. Further, providing feedforward control only over state S1 during the relatively short time period of 25 μs significantly reduces the required number of samples, since no feedforward control data collection occurs over states S2 and S3. This significantly reduces memory requirements, freeing up memory to potentially store data from multiple prior feedforward control iterations or for other purposes. At a sampling rate of 600 ns, approximately 42 samples are required in order to sample over the entire 25 μs period of S1.

As described above, in various configurations, an envelope or pulse can include sections, subsections, regions, or sub-regions for which feedforward control can be implemented, in combination with or separate from feedback control. By way of nonlimiting example, a sub-region can be of interest with respect to providing feedforward control at other than a state S1, S2, . . . , Sn or a transition associated with one or more states. By way of nonlimiting example, by monitoring the actual output, it may be determined that the actual output or output profile has a sub-region with an undesirable shape that is not a state transition, but could benefit from feedforward control. Such an undesirable shape could result from, by way of nonlimiting example, the actions of other generators in the system affecting the load impedance. The states and the undesirable shapes can be collectively referred to as respective areas of interest.

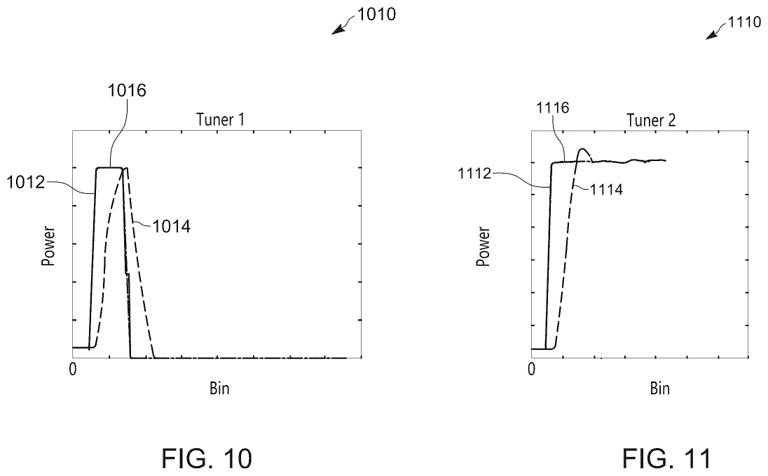

FIG. 10 shows waveforms 1010 which describe operation of the sub-region tuning method described herein using a first tuner, Tuner 1, over a first sub-region of an envelope or pulse. Desired state or pulse state, such as one of states or pulse states S1, S2, . . . , Sn, is shown at waveform 1012 and has a relatively narrow duration or period. In various configurations, waveform 1010 may correspond to state 912 of FIG. 9. An actual output pulse based upon, in one nonlimiting example, desired state S1 is shown at waveform 1014 and indicates the actual output using feedback control. Waveform 1016 indicates the actual output of state S1 using feedforward control in combination with feedback control. Further, in various configurations, waveform 1016 can represent the actual output of state S1 using only feedforward control with no feedback control.

FIG. 11 shows waveforms 1110 which describe operation of the sub-region tuning method described herein using a second tuner, Tuner 2, over a second sub-region of an envelope or pulse. Desired state or pulse state, such as one of states or pulse states S1, S2, . . . , Sn, is shown at waveform 1112 and has a longer duration or period than pulse state S1 of FIG. 10. In various configurations, waveform 1110 may correspond to the positive-going transition of state 916 of FIG. 9. An actual output pulse based upon, in one nonlimiting example, desired state S2 is shown at waveform 1114 and indicates the actual output using either feedback control. Waveform 1116 indicates the actual output of state S2 using feedforward control in combination with feedback control. Further, in various configurations, waveform 1116 may represent the actual output of state S2 using only feedforward control with no feedback control.

Pulse state S2 of FIG. 11 has a longer duration or period than pulse state S1 of FIG. 10. The approach described herein can apply to both narrower states, such as state S1, and wider states, such as state S2. In various configurations, as described above, Tuner 1 and Tuner 2 may be two separate, identically or differently configured tuners. In various other configurations, also as described above, Tuner 1 and Tuner 2, may be the same tuner and actuated during states S1 and S2 and deactuated otherwise.

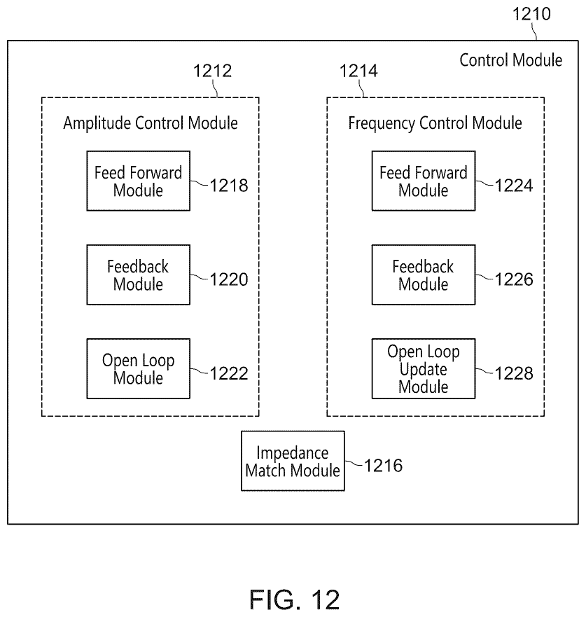

FIG. 12 incorporates various components of FIGS. 1-11. Control module 1210 may include amplitude control module section 1212, frequency control module section 1214, and impedance match module section 1216. Amplitude control module section 1212 includes feedforward module 1218, feedback module 1220, and open loop module 1222. Frequency control module section 1214 includes feedforward module 1224, feedback module 1226, and open loop module 1228. Impedance match module section 1216 may be similarly configured as amplitude control module section 1212 and frequency control module section 1214 to include feedforward, feedback, and open-loop control modules. In various configurations, one or more of respective feedback modules and open-loop modules may be omitted from one or more of respective amplitude control module section 1212, frequency control module section 1214, and impedance matched module section 1216. In various configurations, control module 1210 includes one or a plurality of processors that execute code associated with the module sections or modules 1210, 1212, 1214, 1216, 1218, 1220, 1222, 1224, 1226, and 1228. Operation of the module sections or modules 1210, 1212, 1214, 1216, 1218, 1220, 1222, 1224, 1226, and 1228 is described below with respect to the method of FIG. 12.

For further defined structure of controllers of FIGS. 1-11, see the below provided flow chart of FIG. 12 and the below provided definition for the term “module”. The systems disclosed herein may be operated using numerous methods, examples, and various control system methods of which are illustrated in FIGS. 1-11. Although the following operations are primarily described with respect to the implementations of FIG. 1, the operations may be easily modified to apply to other implementations of the present disclosure. The operations may be iteratively performed. Although the following operations are shown and primarily described as being performed sequentially, one or more of the following operations may be performed while one or more of the other operations are being performed.

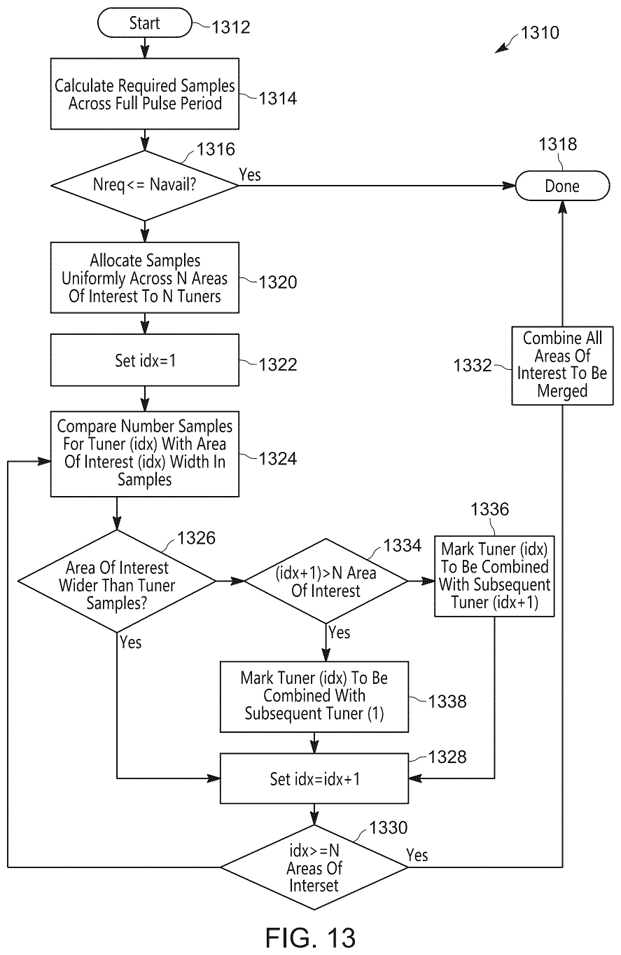

FIG. 13 shows a flow chart of a control system 1310 for determining pulse shaping regions for applying sub-region tuning control for, by way of nonlimiting example, the power delivery systems of FIG. 12. Control begins at 1312 and proceeds to 1314. At 1314, the number of required samples is determined if sampling were to occur over a full envelope or pulse period. By way of nonlimiting example, if the pulse period is 100 Hz, and the sampling period is 600 ns, approximately 16,666 samples are required to apply feedforward control over the entire 100 Hz period. Control proceeds to 1316 which determines if the number of required samples is less than the number of available memory locations to store the samples. If the number of required samples is less than the number of available locations to store the samples, control proceeds to 1318 and the process terminates because there is sufficient memory to sample over the entire envelope or pulse period.

If there is not a sufficient number of available memory locations, control proceeds to 1320 where the samples are allocated uniformly across N areas of interest to N respective tuners or sub-regions. For the discussion herein, areas of interest may include areas of interest as described above, which may include a state, a transition region, or an undesirable shape. The number of available samples are allocated uniformly across the N areas of interest by dividing the number of samples by N, thereby allocating (number of samples/N) samples to each tuner.

Control proceeds to 1322 which sets a starting tuner index of 1. Control proceeds to 1324 where it is determined whether the width of the area of interest is less than or greater than the width of the number of tuner samples. Control then proceeds to 1326. At 1326, if the area of interest is wider than the width of the number of tuner samples, the samples are allocated across the area of interest and control proceeds to 1328. At 1328, the tuner index (idx) is incremented in anticipation of processing the next area of interest, and control proceeds to 1330, where control determines whether all area of interest have been processed by comparing the tuner index (idx) to N, the number of areas of interest (N). If the tuner index (idx) is greater than or equal to the number of areas of interest (N), control proceeds to 1332. At 1332, all areas of interest to be merged are combined. From 1332, control proceeds to 1318 and terminates.

Returning to 1326, if the area of interest is not wider than the width of the number of tuner samples, the areas of interest overlap and control proceeds to 1334 where it is determined if the next tuner index (idx+1) is greater than the number of area of interest (N). If the next tuner index (idx+1) is less than the areas of interest (N), control proceeds to 1336. At 1336, the current tuner index (idx+1) is marked for combining with subsequent tuner index (idx+1), so tuner (idx) and tuner (idx) will be combined. Returning to 1334 if the subsequent tuner index (idx+1) is greater than the areas of interest (N), control proceeds to 1338 which designates the present tuner index (idx) to be combined with the subsequent (first) tuner index (1) of the next envelope or pulse. Thus, 1334 determines if a wraparound condition exists so that the present area of interest is in a position in the envelope or pulse, such as at an end position, where it is combined with the first area of interest of a subsequent envelope or pulse, such as at a beginning position.

Control then proceeds to 1328 which increments the area of interest. Control next proceeds to 1330 which determines if all areas of interest have been processed by determining if the present region of interest (idx) is greater than or equal to the total number of areas of interest (N). If all areas of interest have been processed, control proceeds to 1332 which combines all areas of interest to be merged. At 1332, regions of interest that are sufficiently close or narrow so that all samples occur within the sample width determined at 1324 are combined.

Feedforward control effects playback of a predetermined set of offset or adjustment values to cause an actual output to approximate a desired output. Such feedforward control benefits from repeatability of a desired pulse shape. When the desired pulse shape is repeatedly requested, it may be determined that the stored profile of offset or adjustment values, such as next actuator profile 770 or 870 of respective FIGS. 7 and 8, correspondingly repeats. Continuous repetition provides flexibility regarding when to initiate playback of the stored actuator profile. In various configurations, playback begins coincident with the PULSE SYNC signal. In other various configurations, playback begins relative to the PULSE SYNC signal so that initiation of a stored actuator profile may occur intermediate to the envelope or pulse having a starting position indicated by the PULSE SYNC signal. Thus, playback can be scheduled to commence within the envelope or pulse signal at a position intermediate to its endpoints. Since the envelope or pulse signal repeats, continuous playback of the actuator profile provides offsets or adjustments over the regions of interest of the envelope or pulse and thus provides feedforward control over all regions of interest.

In various configurations, the actuator profile stored in learning module 864 may include a plurality of presets stored in learning module 864. The plurality of presets may include tuner allocations across the pulse period so that when prior, known envelope or pulse shapes are requested, learning module 864 may reference a database of stored presets that provide an initial actuator profile generated from prior data collection of a similarly shaped envelope or pulse. In various other configurations, selected regions of interest of the envelope or pulse can be excluded when allocating tuners across the pulse if various applications do not require the accuracy offered by feedforward control in the selected areas of interest. Further, in various configurations, customer requirements for improved control over certain areas of interest of the envelope or pulse could be used to allocate samples for improved feedback control in the certain regions. In various other embodiments, MIMO applications may allocate tuners and samples differently for each actuator. In one nonlimiting example with respect to FIG. 5, feedforward controller 540 may allocate samples differently for generating the drive adjustment or offset than for generating the frequency adjustment or offset. Further, in various embodiments, tuner sample allocations can be revised dynamically. In one nonlimiting example, areas of interest with smooth feedforward actuator content could be reallocated to other areas of interest of the envelope or pulse period so that fewer samples are required where feedforward control may not be beneficial, such as in smooth regions. The additional samples can be reallocated to regions with a greater magnitude of error and, therefore, a larger opportunity for benefitting from the feedforward control.

The above described system may offer improved tuning speeds resulting from a reduced volume of data collection and the subsequent processing of smaller data vectors. Further, since the data collection overhead is reduced, resulting memory savings can enable feedforward control of multiple actuators, multiple outputs, smaller sampling periods, or higher order feedforward methods.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. In the written description and claims, one or more steps within a method may be executed in a different order (or concurrently) without altering the principles of the present disclosure. Similarly, one or more instructions stored in a non-transitory computer-readable medium may be executed in a different order (or concurrently) without altering the principles of the present disclosure. Unless indicated otherwise, numbering or other labeling of instructions or method steps is done for convenient reference, not to indicate a fixed order.

Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements.

The phrase “at least one of A, B, and C” should be construed to mean a logical (A OR B OR C), using a non-exclusive logical OR, and should not be construed to mean “at least one of A, at least one of B, and at least one of C.” The term “set” does not necessarily exclude the empty set—in other words, in some circumstances a “set” may have zero elements. The term “nonempty set” may be used to indicate exclusion of the empty set—in other words, a nonempty set will always have one or more elements. The term “subset” does not necessarily require a proper subset. In other words, a “subset” of a first set may be coextensive with (equal to) the first set. Further, the term “subset” does not necessarily exclude the empty set—in some circumstances a “subset” may have zero elements.

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” can be replaced with the term “controller” or the term “circuit.” In this application, the term “controller” can be replaced with the term “module.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); processor hardware (shared, dedicated, or group) that executes code; memory hardware (shared, dedicated, or group) that stores code executed by the processor hardware; other suitable hardware components that provide the described functionality; or a combination of some or all of the above, such as in a system-on-chip.

The module may include one or more interface circuits. In some examples, the interface circuit(s) may implement wired or wireless interfaces that connect to a local area network (LAN) or a wireless personal area network (WPAN). Examples of a LAN are Institute of Electrical and Electronics Engineers (IEEE) Standard 802.11-2020 (also known as the WIFI wireless networking standard) and IEEE Standard 802.3-2018 (also known as the ETHERNET wired networking standard). Examples of a WPAN are IEEE Standard 802.15.4 (including the ZIGBEE standard from the ZigBee Alliance) and, from the Bluetooth Special Interest Group (SIG), the BLUETOOTH wireless networking standard (including Core Specification versions 3.0, 4.0, 4.1, 4.2, 5.0, and 5.1 from the Bluetooth SIG).

The module may communicate with other modules using the interface circuit(s). Although the module may be depicted in the present disclosure as logically communicating directly with other modules, in various implementations the module may actually communicate via a communications system. The communications system includes physical and/or virtual networking equipment such as hubs, switches, routers, and gateways. In some implementations, the communications system connects to or traverses a wide area network (WAN) such as the Internet. For example, the communications system may include multiple LANs connected to each other over the Internet or point-to-point leased lines using technologies including Multiprotocol Label Switching (MPLS) and virtual private networks (VPNs).

In various implementations, the functionality of the module may be distributed among multiple modules that are connected via the communications system. For example, multiple modules may implement the same functionality distributed by a load balancing system. In a further example, the functionality of the module may be split between a server (also known as remote, or cloud) module and a client (or, user) module. For example, the client module may include a native or web application executing on a client device and in network communication with the server module.

Some or all hardware features of a module may be defined using a language for hardware description, such as IEEE Standard 1364-2005 (commonly called “Verilog”) and IEEE Standard 1076-2008 (commonly called “VHDL”). The hardware description language may be used to manufacture and/or program a hardware circuit. In some implementations, some or all features of a module may be defined by a language, such as IEEE 1666-2005 (commonly called “SystemC”), that encompasses both code, as described below, and hardware description.

The term code, as used above, may include software, firmware, and/or microcode, and may refer to programs, routines, functions, classes, data structures, and/or objects. Shared processor hardware encompasses a single microprocessor that executes some or all code from multiple modules. Group processor hardware encompasses a microprocessor that, in combination with additional microprocessors, executes some or all code from one or more modules. References to multiple microprocessors encompass multiple microprocessors on discrete dies, multiple microprocessors on a single die, multiple cores of a single microprocessor, multiple threads of a single microprocessor, or a combination of the above.

The memory hardware may also store data together with or separate from the code. Shared memory hardware encompasses a single memory device that stores some or all code from multiple modules. One example of shared memory hardware may be level 1 cache on or near a microprocessor die, which may store code from multiple modules. Another example of shared memory hardware may be persistent storage, such as a solid state drive (SSD), which may store code from multiple modules. Group memory hardware encompasses a memory device that, in combination with other memory devices, stores some or all code from one or more modules. One example of group memory hardware is a storage area network (SAN), which may store code of a particular module across multiple physical devices. Another example of group memory hardware is random access memory of each of a set of servers that, in combination, store code of a particular module.

The term memory hardware is a subset of the term computer-readable medium. The term computer-readable medium, as used herein, does not encompass transitory electrical or electromagnetic signals propagating through a medium (such as on a carrier wave); the term computer-readable medium is therefore considered tangible and non-transitory. Nonlimiting examples of a non-transitory computer-readable medium are nonvolatile memory devices (such as a flash memory device, an erasable programmable read-only memory device, or a mask read-only memory device), volatile memory devices (such as a static random access memory device or a dynamic random access memory device), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. Such apparatuses and methods may be described as computerized apparatuses and computerized methods. The functional blocks and flowchart elements described above serve as software specifications, which can be translated into the computer programs by the routine work of a skilled technician or programmer.

The computer programs include processor-executable instructions that are stored on at least one non-transitory computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation), (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Perl, Pascal, Curl, OCaml, JavaScript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A controller for a generator comprising:
a feedforward control module, the feedforward control module configured to generate an adjustment profile to control a parameter of a generator in accordance with a desired output signal,
wherein the feedforward control module generates a plurality of adjustment values in accordance with sub-regions of the output signal, wherein each sub-region includes a portion of the desired output signal.

2. The controller of claim 1, wherein the feedforward control module receives a synchronization signal, wherein the synchronization signal indicates a relative position of the desired output signal.

3. The controller of claim 1, wherein the desired output signal is a multistate pulse signal having a period.

4. The controller of claim 1, wherein a sub-region may be one of a state of a multistate pulse of the desired output signal, a transition of the desired output signal, or an area of interest of the desired output signal.

5. The controller of claim 1, wherein the feedforward control module includes a plurality of tuners, wherein each tuner provides feedforward control for a respective sub-region, or wherein the feedforward control module includes a single tuner, wherein the single tuner provides feedforward control over each sub-region and does not provide feedforward control for other than each sub-region.

6. The controller of claim 1, wherein the feedforward control module further comprises:
first memory for storing at least one actuator profile, wherein the at least one actuator profile varies in accordance with at least one prior actuator profile;
second memory for storing at least one output profile, wherein the at least one output profile varies in accordance with at least one parameter of the output signal; and
a learning module configured to receive the at least one actuator profile and the at least one output profile and generating the adjustment profile in accordance with at least one of a prior adjustment profile, the at least one actuator profile, or the at least one output profile.

7. The controller of claim 1, wherein the generator is one of a voltage, current, power, or RF generator.

8. The controller of claim 1, wherein the feedforward control module allocates samples to each sub-region in accordance with at least one of a number of available samples or a number of sub-regions, wherein one of an equal number of samples are allocated to each sub-region or a different number of samples are allocated to a pair of sub-regions.

9. The controller of claim 8, wherein the different number of samples are allocated dynamically in accordance with at least one of smooth feedforward actuator content or magnitude of error.

10. The controller of claim 8, wherein one of:
if a pair of sub-regions are arranged so that allocated samples of each sub-region partially overlap, the feedforward control module combines the pair of sub-regions to define a combined sub-region, or
if a pair of sub-regions are arranged at an end of the desired output signal and at a beginning of a next the desired output signal and the allocated samples of each sub-region partially overlap, the feedforward control module combines the pair of sub-regions to define a combined sub-region.

11. The controller of claim 1, further comprising:
at least one of a feedback control module or an open loop control module,
wherein in each sub-region, both feedback and feedforward control are used to control a parameter of the generator, and
wherein for other than the sub-regions, one of feedforward or open loop control adjusts the parameter of the generator.

12. A non-transitory computer-readable medium storing processor-executable instructions, the instructions comprising:
generating by a feedforward control module an adjustment profile to control a parameter of a generator in accordance with a desired output signal; and
generates a plurality of adjustment values in accordance with sub-regions of the output signal, wherein each sub-region includes a portion of the desired output signal,
wherein a sub-region may be one of a state of a multistate pulse of the desired output signal, a transition of the desired output signal, or an area of interest of the desired output signal.

13. The non-transitory computer-readable medium storing processor-executable instructions of claim 12, further comprising receiving a synchronization signal, wherein the synchronization signal indicates a relative position of the desired output signal.

14. The non-transitory computer-readable medium storing processor-executable instructions of claim 12, wherein the feedforward control module includes a plurality of tuners, wherein each tuner provides feedforward control for a respective sub-region, or wherein the feedforward control module includes a single tuner, wherein the single tuner provides feedforward control over each sub-region and does not provide feedforward control for other than each sub-region.

15. The non-transitory computer-readable medium storing processor-executable instructions of claim 12, further comprising:
storing at least one actuator profile in first memory, wherein the at least one actuator profile varies in accordance with at least one prior actuator profile;
storing at least one output profile in second memory, wherein the at least one output profile varies in accordance with at least one parameter of the output signal; and
receiving the at least one actuator profile and the at least one output profile and generating the adjustment profile in accordance with at least one of at least one adjustment profile, the at least one actuator profile, or the at least one output profile.

16. The non-transitory computer-readable medium storing processor-executable instructions of claim 12, further comprising allocating samples to each sub-region in accordance with at least one of a number of available samples or a number of sub-regions, wherein one of an equal number of samples are allocated to each sub-region or a different number of samples are allocated to a pair of sub-regions, wherein the different number of samples are allocated dynamically in accordance with at least one of smooth feedforward actuator content or magnitude of error.

17. The non-transitory computer-readable medium storing processor-executable instructions of claim 16, wherein one of:
if a pair of sub-regions are arranged so that the allocated samples of each sub-region partially overlap, combining the pair of sub-regions to define a combined sub-region, or
if a pair of sub-regions are arranged at an end of the desired output signal and at a beginning of a next the desired output signal and the allocated samples of each sub-region partially overlap, combining the pair of sub-regions to define a combined sub-region.

18. A power supply system comprising:
a RF generator configured to output a desired output signal to a load; and
a controller for a generator including a feedforward control module, the feedforward control module configured to generate an adjustment profile to control a parameter of a generator in accordance with a desired output signal,
wherein the feedforward control module generates a plurality of adjustment values in accordance with sub-regions of the output signal, wherein each sub-region includes a portion of the desired output signal.

19. The power supply system of claim 18, wherein the feedforward control module includes a plurality of tuners, wherein each tuner provides feedforward control for a respective sub-region, or wherein the feedforward control module includes a single tuner, wherein the single tuner provides feedforward control over each sub-region and does not provide feedforward control for other than each sub-region.

20. The power supply system of claim 18, wherein the feedforward control module allocates samples to each sub-region in accordance with at least one of a number of available samples or a number of sub-regions, wherein one of an equal number of samples are allocated to each sub-region or a different number of samples are allocated to a pair of sub-regions.
